(19) United States
(12) Patent Application Publication
(10) Pub. No.: US 2025/0089156 A1
(43) Pub. Date: Mar. 13, 2025

(54) LOW STRESS THROUGH GLASS VIAS (TGVS)

(71) Applicant: Intel Corporation, Santa Clara, CA (US)

(72) Inventors: Mohamed R. SABER, College Station, TX (US); Manohar KONCHADY, Chandler, AZ (US); Srinivas Venkata Ramanuja PIETAMBARAM, Chandler, AZ (US); Hiroki TANAKA, Gilbert, AZ (US); Gang DUAN, Chandler, AZ (US)

(21) Appl. No.: 18/367,963

(22) Filed: Sep. 13, 2023

(51) Int. Cl. H05K 1/02; H01L 23/15; H01L 23/498; H05K 1/03; H05K 1/11

(52) U.S. Cl. CPC H05K 1/0271; H01L 23/15; H01L 23/49827; H01L 23/49894; H05K 1/0306; H05K 1/116; H05K 2201/026; H05K 2201/0323

(57) ABSTRACT

Embodiments disclosed herein include an apparatus with a glass core and a via. In an embodiment, the apparatus comprises a layer, where the layer is a solid layer of glass. An opening is provided through the layer, and a via is in the opening. The via comprises a first material, where the first material comprises at least one metallic element, and a second material, where the second material comprises carbon.

### BACKGROUND

Coefficient of thermal expansion (CTE) mismatches between different components within a system can lead to significant integration challenges. Glass core packages may be particularly susceptible to damage or other negative factors that arise from CTE mismatches. For example, conductive vias are formed through the glass core of the package substrate in order to provide electrical connections between the top surface and the bottom surface of the core. However, the CTE of the via (which is typically copper or a copper alloy) is significantly higher than the CTE of the glass. The CTE of glass may be around 5 parts per million/° C. (ppm/° C.) or less, and the CTE of copper is around 15 ppm/° C. or greater.

During annealing processes or other thermal cycling, the via expands more than the glass. This leads to stress on the glass, which can ultimately lead to crack propagation. Accordingly, glass core substrates can exhibit lower mechanical robustness compared to traditional organic core package substrates. This leads to lower yields and an increase in overall cost of manufacturing glass core substrates suitable for mass production.

### BRIEF DESCRIPTION OF THE DRAWINGS

FIG. 1A is a cross-sectional illustration of a core that includes a glass layer with through glass vias, in accordance with an embodiment.

FIG. 1B is a cross-sectional illustration of the core after a crack has propagated out from the edge of the via due to CTE mismatch between the via and the glass core, in accordance with an embodiment.

FIG. 2A is a cross-sectional illustration of a core that includes a glass layer with through glass vias that are formed with a composite structure including copper and carbon nanomaterial dopants, in accordance with an embodiment.

FIG. 2B is a cross-sectional illustration of a core that includes a glass layer with composite vias that are lined by a compressible liner, in accordance with an embodiment.

FIG. 3A is a cross-sectional illustration of a glass core with via openings, in accordance with an embodiment.

FIG. 3B is a cross-sectional illustration of a glass core with a seed layer deposited over the sidewalls of the via openings, in accordance with an embodiment.

FIG. 3C is a cross-sectional illustration of a glass core with a composite via disposed in the via opening over the seed layer, in accordance with an embodiment.

FIG. 4A is a cross-sectional illustration of a glass core with via openings that are filled with vias that comprise carbon, such as carbon nanotubes, in accordance with an embodiment.

FIG. 4B is a cross-sectional illustration of a glass core with via openings with a carbon based via that is lined by a liner, in accordance with an embodiment.

FIG. 5A is a cross-sectional illustration of a glass core, in accordance with an embodiment.

FIG. 5B is a cross-sectional illustration of a glass core after the formation of via openings, in accordance with an embodiment.

FIG. 5C is a cross-sectional illustration of the glass core and a second substrate with a catalyst layer, in accordance with an embodiment.

FIG. 5D is a cross-sectional illustration of the glass core attached to the second substrate with the catalyst layer exposed in the via openings, in accordance with an embodiment.

FIG. 5E is a cross-sectional illustration of the glass core after the vias have been deposited in the via openings, in accordance with an embodiment.

FIG. 5F is a cross-sectional illustration of the glass core after excess portions of the via and the second substrate are removed, in accordance with an embodiment.

FIG. 6 is a cross-sectional illustration of a glass core with an array of vias that are composites of copper and carbon, in accordance with an embodiment.

FIG. 7 is a cross-sectional illustration of an electronic system with a glass core package substrate that includes composite through glass vias, in accordance with an embodiment.

FIG. 8 is a schematic of a computing device built in accordance with an embodiment.

### EMBODIMENTS OF THE PRESENT DISCLOSURE

Described herein are electronic systems, and more particularly, electronic systems with glass substrates that include through glass vias (TGVs) that are filled with a low coefficient of thermal expansion (CTE) material, in accordance with various embodiments. In the following description, various aspects of the illustrative implementations will be described using terms commonly employed by those skilled in the art to convey the substance of their work to others skilled in the art. However, it will be apparent to those skilled in the art that the present disclosure may be practiced with only some of the described aspects. For purposes of explanation, specific numbers, materials and configurations are set forth in order to provide a thorough understanding of the illustrative implementations. However, it will be apparent to one skilled in the art that the present disclosure may be practiced without the specific details. In other instances, well-known features are omitted or simplified in order not to obscure the illustrative implementations.

Various operations will be described as multiple discrete operations, in turn, in a manner that is most helpful in understanding the present disclosure, however, the order of description should not be construed to imply that these operations are necessarily order dependent. In particular, these operations need not be performed in the order of presentation.

As package substrates advance to smaller feature sizes, larger footprints, and thinner substrates, there has been a drive to enable glass core substrates. Glass cores have been proposed to replace traditional organic core materials due to their improved performance metrics. However, the move to glass cores is not without issue. One issue that should be addressed is associated with CTE mismatches between materials. Particularly, the CTE of the glass core is significantly lower than the CTE of the via material (which is typically copper or a copper alloy). During annealing process, reflow processes, or other thermal cycling, the via may expand more than the glass layer. This can result in stress being applied to the glass core. The stress can produce cracks or other defects. As such, mechanical and electrical reliability and/or robustness of the core can be negatively impacted.

One solution that has been proposed is to provide a liner around the vias. The liner may have a low modulus. A low modulus material may be used to absorb some or all of the stress that would otherwise be applied to the glass by the expanding via. However, the use of liners is not without issue. For one, the addition of a liner requires an additional processing operation. Further, the liner further increases the aspect ratio of the opening. This makes the opening harder to fill without forming voids that negatively impact electrical performance and reliability. Accordingly, alternative solutions are desired.

Embodiments disclosed herein provide improved via material engineering in order to reduce or eliminate CTE mismatch between the via and the glass core. In some embodiments, the via may comprise a composite material. The composite material may comprise a first material, such as copper, and a second material that functions as a dopant or filler. The second material may be dispersed within the first material (e.g., homogenously distributed). Ideally, the second material should reduce the CTE of the via without negatively impacting the electrical performance of the via. For example, carbon nanomaterials may be used as the second material. In order to maintain electrical performance, the carbon may be in the form of carbon nanotubes, graphene, or the like.

In another embodiment, a metallic based via may be replaced with an electrically conductive carbon based via. For example, a carbon nanotube structure may be provided as the via. Carbon nanotubes have a significantly lower CTE than copper, while still maintaining similar electrical performance. As such, the via does not provide stress on the glass core during thermal cycling, and the via still enables excellent electrical performance.

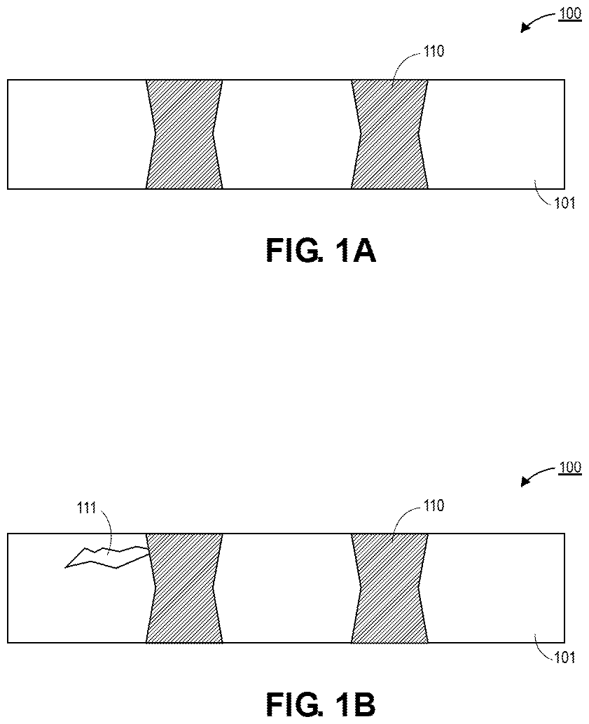

Referring now to FIG. 1A, a cross-sectional illustration of a core 100 is shown, in accordance with an embodiment. The core 100 may be part of a package substrate. That is, layers of dielectric material (e.g., organic dielectric material) may be provided above and/or below the core 100. The core 100 may comprise a glass layer 101. The glass layer 101 may be substantially all glass. That is, the glass layer 101 is distinct from a traditional core that includes organic material that is reinforced with glass fibers or the like.

The core 100 may include vias 110. The vias 110 may pass through a thickness of the glass layer 101. The vias 110 may be electrically conductive in order to provide electrical coupling between the bottom surface and the top surface of the glass layer 101. For example, traditional cores 100 may include a metallic via 110, such as one comprising copper or a copper alloyed with one or more different elements. The via 110 may have tapered sidewalls. In FIG. 1A, the sidewalls include a double tapered shape that forms an hourglass shaped via 110. Though, a single taper may be provided, or the sidewalls may have a substantially vertical profile.

In the case of a copper or copper alloy via 110, the CTE of the via 110 may be significantly different than the CTE of the glass layer 101. Typically, glass has a CTE of approximately 6 ppm/° C. or less, and copper has a CTE of around 16 ppm/° C. Accordingly, the via 110 expands more than the glass layer 101 during thermal cycling. This can result in stress being applied to the glass layer 101. As shown in FIG. 1B, this may result in the formation of cracks 111, or other defects in the glass layer 101. Due to the defects, the glass layer 101 has a decrease in mechanical robustness. This can lead to complete device failures of the core 100 and the overall package substrate. Accordingly, yields decrease and costs increase.

Accordingly, improved embodiments such as those with different via architectures are described herein. As noted above, the different via architectures may result in a decrease in the CTE of the via. This reduces the stress induced into the glass layer and mitigates or prevents the formation of stress induced defects, such as cracks. In one such via architecture, a composite via with a metallic matrix (e.g., copper) and carbon containing particles (e.g., nanotubes or graphene) is used. In another embodiment, the metallic via is completely replaced with a conductive carbon based via, such as one formed from the bulk deposition of carbon nanotubes.

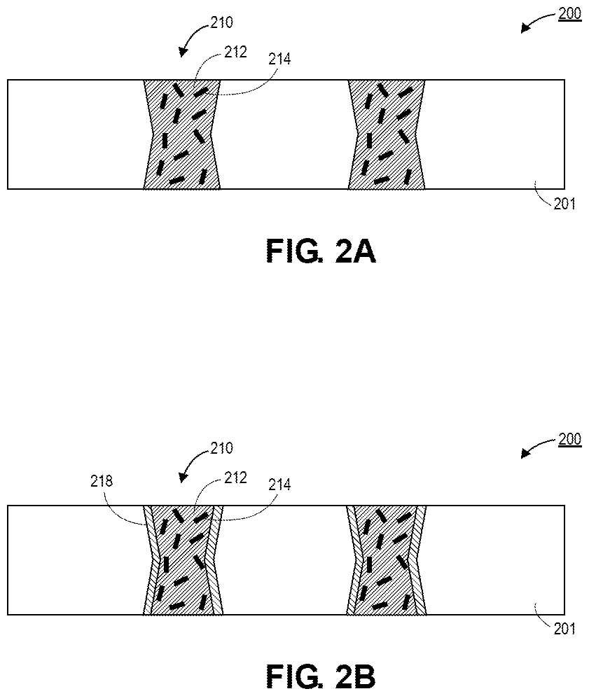

Referring now to FIG. 2A, a cross-sectional illustration of a core 200 is shown, in accordance with an embodiment. In an embodiment, the core 200 may comprise a glass layer 201. The glass layer 201 may be substantially all glass. The glass layer 201 may be a solid material with an amorphous crystal structure. More particularly, the glass layer 201 may be any suitable glass formulation that has the necessary mechanical robustness and compatibility with semiconductor packaging manufacturing and assembly processes. For example, the glass layer 201 may comprise aluminosilicate glass, borosilicate glass, alumino-borosilicate glass, silica, fused silica, or the like. In some embodiments, the glass layer 201 may include one or more additives, such as, but not limited to, Al₂O₃, B₂O₃, MgO, CaO, SrO, BaO, SnO₂, NazO, K₂O, SrO, P₂O₃, ZrO₂, Li₂O, Ti, and Zn. More generally, the glass layer 201 may comprise silicon and oxygen, as well as any one or more of aluminum, boron, magnesium, calcium, barium, tin, sodium, potassium, strontium, phosphorus, zirconium, lithium, titanium, and zinc. In an embodiment, the glass layer 201 may comprise at least 23 percent silicon (by weight) and at least 26 percent oxygen (by weight). In some embodiments, the glass layer 201 may further comprise at least 5 percent aluminum (by weight). The glass layer 201 may have a thickness that is between approximately 100 μm and approximately 1,000 μm. Though, thinner or thicker glass layers 201 may be used in some embodiments. As used herein, “approximately” may refer to a range of values that are within 10 percent of the stated value. For example, “approximately 100 μm” may refer to a range between 90 μm and 110 μm.

In an embodiment, one or more vias 210 may be provided through the thickness of the core 200. The vias 210 may be electrically conductive structures. As such, electrical coupling between the bottom surface of the glass layer 201 and the top surface of the glass layer 201 can be provided. The vias 210 may have any suitable structure. In the example shown in FIG. 2A, the vias 210 have hourglass shaped cross-sections. Though sidewalls of the vias 210 may have sidewalls with a single taper or sidewalls that are substantially vertical. The vias 210 may have minimum diameters that are approximately 10 μm or greater, approximately 50 μm or greater, or approximately 100 μm or greater. Though, minimum diameters less than 10 μm may also be obtainable with some embodiments.

In an embodiment, the openings through the glass layer 201 in which the vias 210 are positioned may be formed with any suitable manufacturing process. For example, tapered sidewall openings may be characteristic of a laser assisted etching process (e.g., laser induced deep etching). Other patterning solutions, such as mechanical drilling, chemical etching (wet or dry), or the like may be used in order to form the openings for the vias 210.

In an embodiment, the vias 210 may have a composite structure. A composite structure may refer to a component that has at least a first material 212 and a second material 214. The first material 212 may be a matrix material (or bulk material) and the second material 214 may be a filler material (or dopant material) that is distributed throughout the first material 212. In some instances the second material 214 is distributed homogeneously throughout the first material 212. In an embodiment, the first material 212 may at least 25 percent (by volume), at least 50 percent (by volume), at least 80 percent (by volume), or at least 95 percent (by volume) of the via 210.

The first material 212 may be a metallic material. For example, the first material 212 may comprise copper or copper and one or more alloying elements. The second material 214 may comprise carbon. The carbon may be in a form that is electrically conductive. For example, the carbon of the second material 214 may include carbon nanotubes, graphene, or the like. In some instances, the second material 214 is pure (or substantially pure) carbon. In other embodiments, the second material 214 may include carbon structures that are doped with one or more different doping elements.

Such carbon structures have a CTE that is significantly lower than that of the first material 212. As such, the composite nature of the via 210 results in a lowered CTE for the via 210. For example, the CTE of the via 210 may be approximately 10 ppm/° C. or less, or approximately 6 ppm/° C. or less. Such low CTE values more closely match the CTE of the glass layer 201. In some embodiments, the resulting CTE of the via 210 may be within 50% of that of the glass layer 201. For example, the CTE of the glass layer 201 may be approximately 6 ppm/° C., and the CTE of the via 210 may be approximately 9 ppm/° C. In other instances, the CTE of the via 210 and the CTE of the glass layer 201 may both be approximately 6 ppm/° C. or less. Due to the reduction in the difference between the CTE of the glass layer 201 and the CTE of the via 210, lower stress is induced on the glass layer 201. This improves mechanical and electrical reliability of the core 200.

In addition to lower CTE values, it is to be appreciated that such composite vias 210 also maintain or improve electrical performance of the via 210. Since carbon nanotubes and graphene are electrically conductive, electrical coupling (i.e., for signal propagation, power delivery, or the like) between the top and bottom of the glass layer 201 is maintained. Such composite vias 210 may also provide improved mechanical performance and/or thermal performance compared to a monolithic copper or copper alloy via previously used.

Referring now to FIG. 2B, a cross-sectional illustration of a core 200 is shown, in accordance with an additional embodiment. In an embodiment, the core 200 may be similar to the core 200 described above with respect to FIG. 2A, with the addition of a liner 218. The liner 218 may have a modulus that is lower than that of the via 210 and the glass layer 201. The liner 218 may be considered a compressible layer. That is, expansion of the via 210 may result in the compression (or narrowing) of the liner 218. The liner 218 may be a polymeric material or any other suitable low modulus material. The use of a liner 218 in combination with a composite via 210 (i.e., one with a first material 212 and a second material 214) may further mitigate the transfer of stress into the glass layer 201 that would otherwise result from CTE mismatch. Accordingly, even when the CTE of the via 210 and the glass layer 201 are not perfectly matched, at least some of the additional stress induced into the glass layer 201 is avoided.

The liner 218 may have any suitable dimensions. Larger thicknesses of the liner 218 may be provided in order to reduce more stress. Though, larger thicknesses for the liner 218 may decrease the diameter of the via opening. This could make deposition of the via 210 more complex, or could require the use of larger via openings in the glass layer 201. However, such a tradeoff may be desirable in situations where improved robustness of the core 200 is desired.

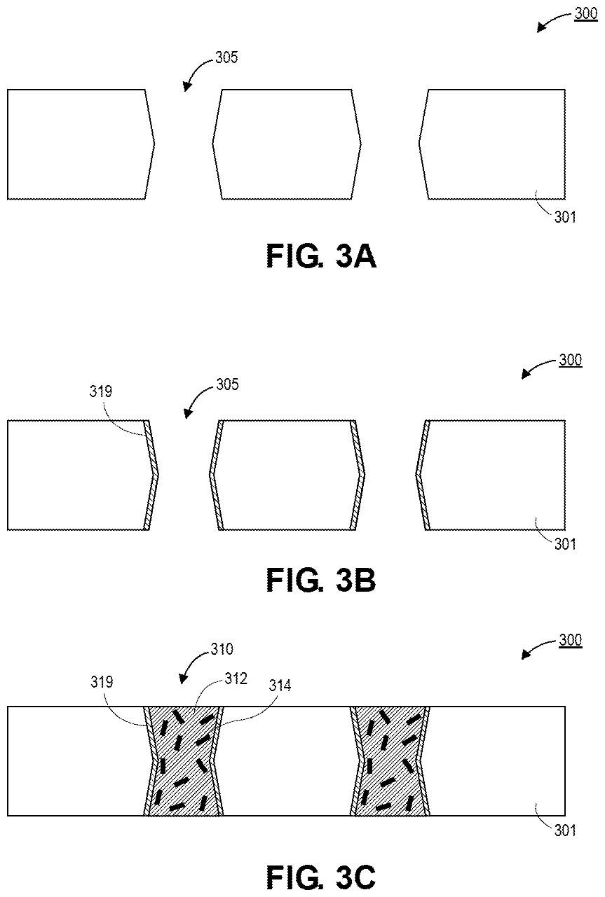

Referring now to FIGS. 3A-3C, a series of cross-sectional illustrations depicting a process for forming a core 300 with composite vias 310 is shown, in accordance with an embodiment. As shown in FIG. 3A, the core 300 may comprise a glass layer 301. The glass layer 301 may be similar in composition and structure as those described in greater detail above. Via openings 305 may be formed through the glass layer 301. For example, a laser assisted etching process, a drilling process, an etching process, or the like may be used in order to form the openings 305. The openings 305 may have tapered sidewalls (e.g., hourglass shaped sidewalls), vertical sidewalls, or any other sidewall profile.

Referring now to FIG. 3B, a cross-sectional illustration of the core 300 after a seed layer 319 is formed over the sidewalls of the via opening 305 is shown, in accordance with an embodiment. In an embodiment, the seed layer 319 may be isolated to within the via openings 305. Though, in other embodiments the seed layer 319 may be blanket deposited over the top surface of the glass layer 301, the bottom surface of the glass layer 301, and the sidewalls of the via openings 305. In such instances, the portions of the seed layer 319 outside of the via openings 305 may be blocked (e.g., with a resist or the like) in order to prevent subsequent plating of conductive material.

The seed layer 319 may be any suitable seed layer formulation. In one instance, the seed layer 319 may comprise copper. Other seed layers may include ruthenium or a combination of copper and ruthenium. The seed layer 319 may have a thickness that is between approximately 1 nm and approximately 500 nm. Though, thinner or thicker seed layers 319 may also be used. The seed layer 319 may be deposited with any suitable deposition process, such as physical vapor deposition (PVD), chemical vapor deposition (CVD), atomic layer deposition (ALD), or the like.

Referring now to FIG. 3C, a cross-sectional illustration of the core 300 after a composite via 310 is formed in the via openings 305 is shown, in accordance with an embodiment. In an embodiment, the via 310 may be formed with an electrodeposition process. Some electrodeposition processes may be used in order to directly deposit both the first material 312 and the second material 314 during a single deposition process (e.g., within a single bath). For example, the first material 312 may comprise copper or a copper alloy, and the second material 314 may comprise electrically conductive carbon, such as carbon nanotubes, graphene, or the like.

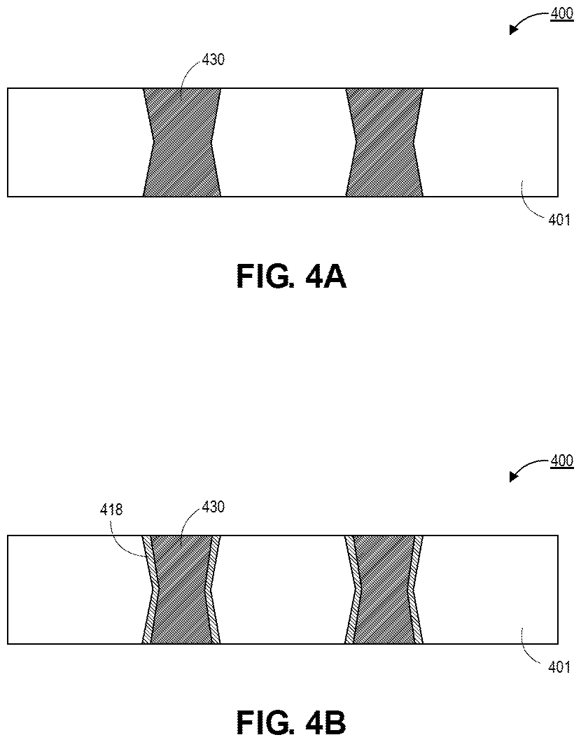

Referring now to FIG. 4A, a cross-sectional illustration of a core 400 is shown, in accordance with an additional embodiment. The core 400 may include a glass layer 401. The glass layer 401 may be a solid material, such as an amorphous glass layer. The glass layer 401 may have a material composition similar to those described in greater detail above. The glass layer 401 may have a thickness that is between approximately 100 μm and approximately 1,000 μm. Though, thinner or thicker glass layers 401 may also be used in some embodiments.

In an embodiment, vias 430 may pass through the glass layer 401. The vias 430 may be electrically conductive materials. Further, the vias 430 may be non-metallic electrical conductors. For example, the vias 430 may comprise carbon, such as carbon nanotubes. That is, the traditional copper or copper alloy via is replaced with a non-metallic via 430. In an embodiment, the via 430 may comprise at least 70 percent (by volume) carbon, at least 95 percent (by volume) carbon, or at least 99 percent (by volume) carbon. In some instances, one or more different elements may be provided with the carbon. For example, carbon nanotubes may be doped with one or more different elements in some instances. Though, substantially pure carbon vias 430 (e.g., comprising carbon nanotube features) may be used in some embodiments as well. Carbon nanotube materials provide excellent electrical conductivity. Depending on the bulk structure of the vias 430, the electrical conductivity of the carbon nanotube vias 430 may even be higher than that of a traditionally used copper via.

Such non-metallic vias 430 are particularly useful due to their lower CTE. Bulk carbon nanotubes may have a CTE that approaches, or is equal to, the CTE of the surrounding glass layer 401. As such, thermal cycling does not induce stress (or induces minimal stress) into the glass layer 401. This allows for improved mechanical and electrical robustness for the core 400. For example, the CTE of carbon nanotubes may be less than 10 ppm/° C., less than 6 ppm/° C., or less than 3 ppm/° C.

Carbon nanotube vias 430 may also provide similar or improved thermal and mechanical performance compared to copper vias. Carbon nanotubes have improved mechanical properties (e.g., modulus, flexibility, etc.). This can lead to improved mechanical robustness of the core 400.

Referring now to FIG. 4B, a cross-sectional illustration of a core 400 is shown, in accordance with an additional embodiment. In an embodiment, the core 400 in FIG. 4B may be similar to the core 400 described above with respect to FIG. 4A, with the addition of a liner 418 around the via 430. The liner 418 may be a low modulus material, such as a polymer or the like. The liner 418 may provide an additional buffer in order to mitigate stress transfer arising from CTE mismatch between the via 430 and the glass layer 401.

The liner 418 may have any suitable dimensions. Larger thicknesses of the liner 418 may be provided in order to reduce more stress. Though, larger thicknesses for the liner 418 may decrease the diameter of the via opening. This could make deposition of the via 410 more complex, or could require the use of larger via openings in the glass layer 401. However, such a tradeoff may be desirable in situations where improved robustness of the core 400 is desired.

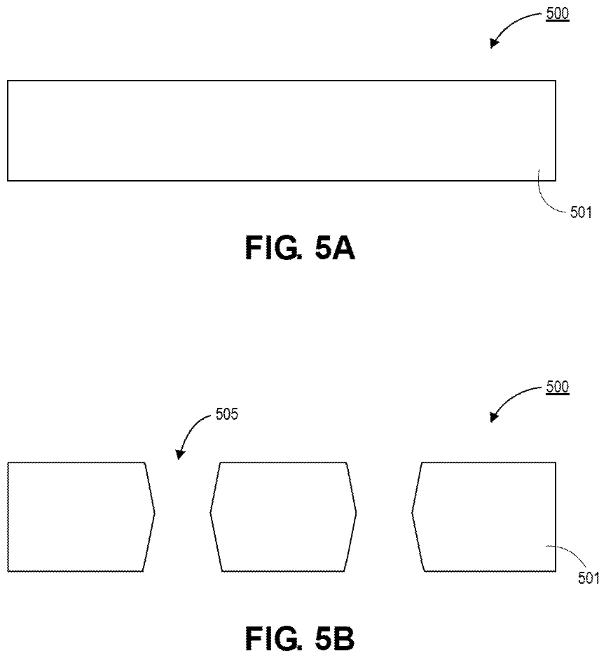

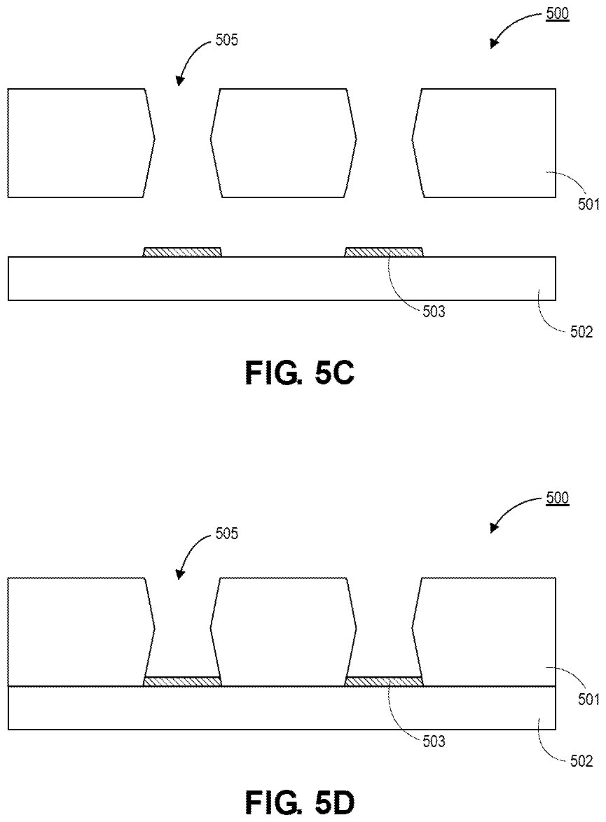

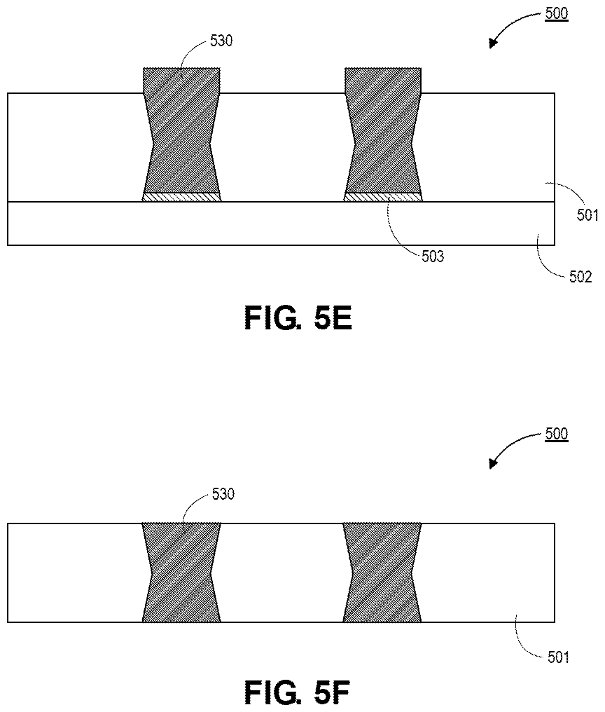

Referring now to FIGS. 5A-5F, a series of cross-sectional illustrations depicting a process for forming a core 500 with non-metallic electrically conductive vias 530 is shown, in accordance with an embodiment. In contrast to the embodiments described above with respect to a composite via structure, the non-metallic electrically conductive vias 530 may be formed with a CVD process or other suitable deposition process, as opposed to an electrodeposition process.

Referring now to FIG. 5A, a cross-sectional illustration of a core 500 is shown, in accordance with an embodiment. The core 500 may comprise a glass layer 501. The glass layer 501 may have a composition and dimensions similar to any of the glass layers described in greater detail above.

Referring now to FIG. 5B, a cross-sectional illustration of the core 500 after via openings 505 are formed through the glass layer 501 is shown, in accordance with an embodiment. The via openings 505 may be formed with any suitable patterning process. For example, a laser assisted patterning process, a mechanical drilling process, an etching process, or the like may be used to form the via openings 505. In the illustrated embodiment, the via openings 505 have an hourglass shaped profile. In other embodiments, the via openings 505 may have sidewalls with a single taper or with a substantially vertical profile.

Referring now to FIG. 5C, a cross-sectional illustration of the core 500 and a corresponding carrier 502 is shown, in accordance with an embodiment. In an embodiment, the carrier 502 may be any suitable rigid material, such as glass, silicon, ceramic, or the like. A catalyst layer 503 may be provided over a top surface of the carrier 502. The catalyst layer 503 may be a material composition suitable for initiating the deposition of carbon nanotubes in a subsequent processing operation. For example, the catalyst layer 503 may comprise one or more of iron, aluminum, and oxygen. In a particular embodiment, the catalyst may comprise Fe/Al₂O₃.

In the illustrated embodiment, the catalyst layer 503 is selectively formed under the via openings 505. Though, in other embodiments, the catalyst layer 503 may be a blanket layer that is provided over an entire top surface of the carrier 502. The overlying glass layer 501 and via openings 505 can then serve as a mask in order to selectively form the vias in a subsequent processing operation.

Referring now to FIG. 5D, a cross-sectional illustration of the core 500 after the glass layer 501 is attached to the carrier 502 is shown, in accordance with an embodiment. As shown, the glass layer 501 is aligned so that the catalyst layer 503 is provided under the via openings 505. The carrier 502 may be attached to the glass layer 501 with any suitable adhesive. For example, a glue or an adhesive layer (e.g., silicon nitride) may be used to secure the carrier 502 to the glass layer 501.

Referring now to FIG. 5E, a cross-sectional illustration of the core 500 after the vias 530 are deposited in the via openings 505 is shown, in accordance with an embodiment. The vias 530 may be formed with any suitable deposition process, such as a CVD process. The catalyst layer 503 enables selective growth of the vias 530 within the via openings 505. In some instances, the deposition process may be run until the vias 530 extend above the top surface of the glass layer 501. Since the catalyst layer 503 is provided below the via openings 505, the vias 530 may be in direct contact with sidewalls of the glass layer 501. That is, there may not be an intervening layer between the via 530 and the glass layer 501, such as a seed layer or the like. In such instances, a material characterization may show a carbon containing region directly contacting the glass composition.

Referring now to FIG. 5F, a cross-sectional illustration of the core 500 after the polishing is shown, in accordance with an embodiment. The polishing process may be used to remove excess via 530 material from above the top surface of the glass layer 501. A detaching process, a polishing process, and/or the like may also be used to remove the carrier 502 from the bottom of the glass layer 501.

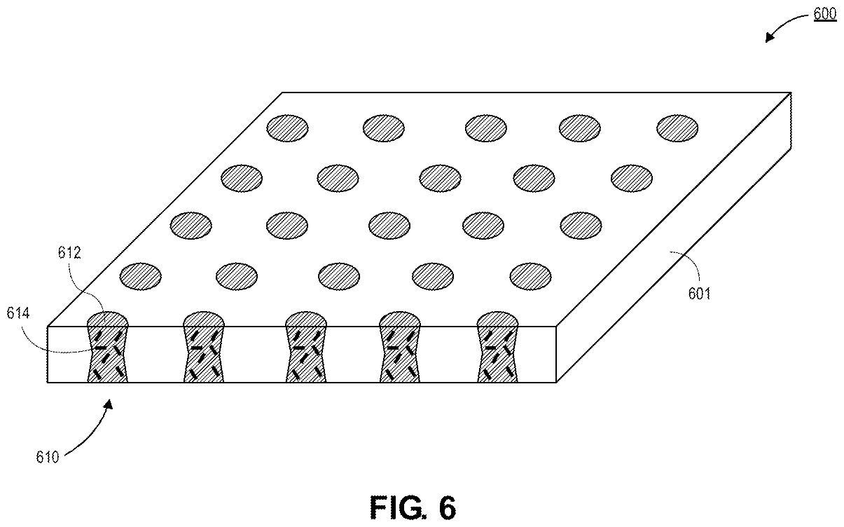

Referring now to FIG. 6, a perspective view illustration of a core 600 is shown, in accordance with an embodiment. The core 600 may include a glass layer 601. The glass layer 601 may have a composition and dimensions similar to any of the glass layers described in greater detail above. In an embodiment, a plurality of vias 610 may pass through the glass layer 601. The vias 610 may be arranged in any suitable pattern or array across the core 600. For example, the vias 610 may have a regular pitch or spacing. Though, arrays with non-uniform pitch and/or non-grid like patterns may also be used in some embodiments.

In the illustrated embodiment, the vias 610 are composite vias 610 with a first material 612 and a second material 614. The first material 612 may be an electrically conductive bulk material, such as copper. The second material 614 may include particles comprising carbon, such as carbon nanotubes, graphene, or the like. Though, in other embodiments, the vias 610 may be replaced with a non-metallic conductor. For example, the non-metallic conductor may include carbon nanotubes.

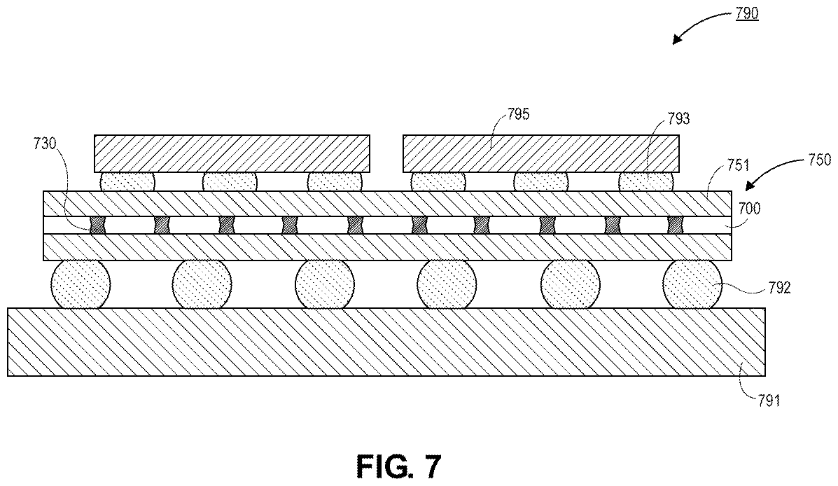

Referring now to FIG. 7, a cross-sectional illustration of an electronic system 790 is shown, in accordance with an embodiment. The electronic system 790 may include a board 791, such as a printed circuit board (PCB). The board 791 may be coupled to a package substrate 750 by interconnects 792. The interconnects 792 may be solder balls (e.g., BGAs), sockets, or the like.

In an embodiment, the package substrate 750 may comprise a core 700. The core 700 may be a glass core, such as one of those described in greater detail above. In an embodiment, vias 730 may be provided through the core 700. The vias 730 shown in FIG. 7 are non-metallic electrical conductors, such as carbon nanotubes. Though, alternative structures, such as vias with a composite composition (e.g., bulk copper with carbon containing filler particles) may also be used. The use of such via 730 architectures may result in less stress on the glass core 700 since there is a reduction in CTE mismatch between materials.

The package substrate 750 may further comprise buildup layers 751 over and/or under the glass core 700. The buildup layers 751 may be organic material, such as buildup film or the like. Conductive routing (e.g., pads, traces, vias, etc.) may be embedded in and/or provided on the buildup layers 751.

In an embodiment, one or more dies 795 may be coupled to the package substrate 750 through interconnects 793. The interconnects 793 may include any first level interconnect (FLI) architecture, such as solder balls, copper bumps, hybrid bonding, or the like. The dies 795 may be compute dies, such as a central processing unit (CPU), a graphics processing unit (GPU), an XPU, or any other type of processor. The dies 795 may also include memory dies, or any other type of necessary peripheral die. In some instances, two or more dies 795 may be communicatively coupled together by a bridge (not shown) that is embedded in the package substrate 750 or provided over the package substrate 750.

It is to be appreciated that the embodiments described in greater detail above may be targeted to glass core architectures that are embedded in a package substrate. However, similar concepts (e.g., reducing CTE mismatch between glass and via through modification of the via composition or structure) can also be implemented on other glass substrate form factors and applications. For example, glass interposers may also include similar via structures. A glass interposer may be provided between a board and a package substrate and/or between a package substrate and the one or more dies.

Further, it is to be appreciated that embodiments disclosed herein are distinct from processes and architectures that use non-metallic based vias at lower levels of semiconductor fabrication. For example, some solutions for providing incredibly fine vias in silicon or other semiconductor substrates have been proposed. However, the difference in via dimensions and substrate composition have significant impacts and generate different manufacturing concerns. Namely, glass is much more susceptible to cracking due to stress induction from CTE mismatch. Additionally, the larger dimensions of the vias described herein (e.g., 10 μm or larger, 150 μm or larger, etc.) result in larger stresses being applied to the surrounding substrate compared to fine via dimensions in lower level silicon fabrication applications. Accordingly, whereas silicon applications may be more concerned about electrical conductivity requirements, embodiments disclosed herein may be particularly applicable to concerns relating to manufacturing robustness, yield, and cost.

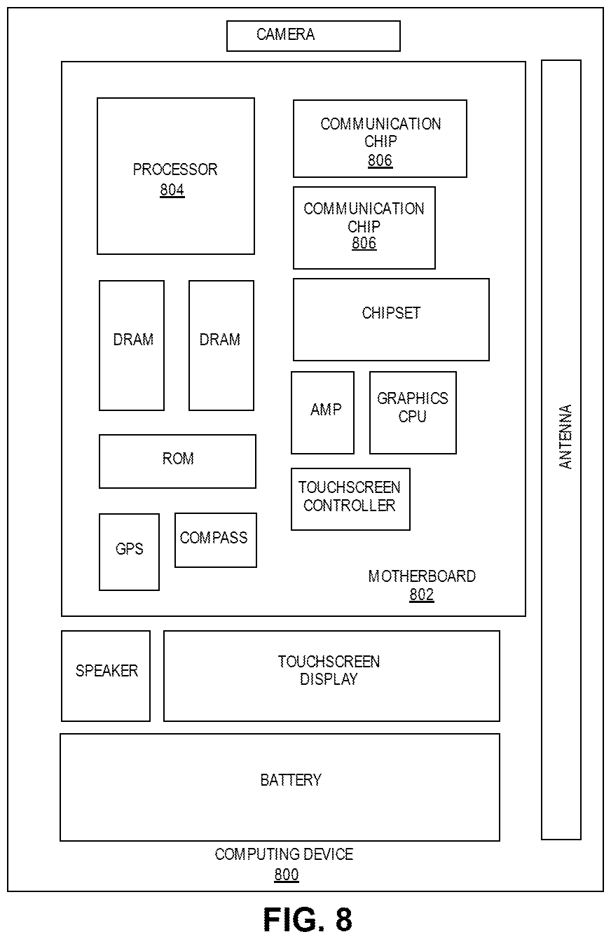

FIG. 8 illustrates a computing device 800 in accordance with one implementation of the disclosure. The computing device 800 houses a board 802. The board 802 may include a number of components, including but not limited to a processor 804 and at least one communication chip 806. The processor 804 is physically and electrically coupled to the board 802. In some implementations the at least one communication chip 806 is also physically and electrically coupled to the board 802. In further implementations, the communication chip 806 is part of the processor 804.

These other components include, but are not limited to, volatile memory (e.g., DRAM), non-volatile memory (e.g., ROM), flash memory, a graphics processor, a digital signal processor, a crypto processor, a chipset, an antenna, a display, a touchscreen display, a touchscreen controller, a battery, an audio codec, a video codec, a power amplifier, a global positioning system (GPS) device, a compass, an accelerometer, a gyroscope, a speaker, a camera, and a mass storage device (such as hard disk drive, compact disk (CD), digital versatile disk (DVD), and so forth).

The communication chip 806 enables wireless communications for the transfer of data to and from the computing device 800. The term “wireless” and its derivatives may be used to describe circuits, devices, systems, methods, techniques, communications channels, etc., that may communicate data through the use of modulated electromagnetic radiation through a non-solid medium. The term does not imply that the associated devices do not contain any wires, although in some embodiments they might not. The communication chip 806 may implement any of a number of wireless standards or protocols, including but not limited to Wi-Fi (IEEE 802.11 family), WiMAX (IEEE 802.16 family), IEEE 802.20, long term evolution (LTE), Ev-DO, HSPA+, HSDPA+, HSUPA+, EDGE, GSM, GPRS, CDMA, TDMA, DECT, Bluetooth, derivatives thereof, as well as any other wireless protocols that are designated as 3G, 4G, 5G, and beyond. The computing device 800 may include a plurality of communication chips 806. For instance, a first communication chip 806 may be dedicated to shorter range wireless communications such as Wi-Fi and Bluetooth and a second communication chip 806 may be dedicated to longer range wireless communications such as GPS, EDGE, GPRS, CDMA, WiMAX, LTE, Ev-DO, and others.

The processor 804 of the computing device 800 includes an integrated circuit die packaged within the processor 804. In some implementations of the disclosure, the integrated circuit die of the processor may be part of an electronic package that includes a package substrate with a glass core that includes vias with either a composite material composition or a non-metallic conductor composition, in accordance with embodiments described herein. The term “processor” may refer to any device or portion of a device that processes electronic data from registers and/or memory to transform that electronic data into other electronic data that may be stored in registers and/or memory.

The communication chip 806 also includes an integrated circuit die packaged within the communication chip 806. In accordance with another implementation of the disclosure, the integrated circuit die of the communication chip may be part of an electronic package that includes package substrate with a glass core that includes vias with either a composite material composition or a non-metallic conductor composition, in accordance with embodiments described herein.

In an embodiment, the computing device 800 may be part of any apparatus. For example, the computing device may be part of a personal computer, a server, a mobile device, a tablet, an automobile, or the like. That is, the computing device 800 is not limited to being used for any particular type of system, and the computing device 800 may be included in any apparatus that may benefit from computing functionality.

The above description of illustrated implementations of the disclosure, including what is described in the Abstract, is not intended to be exhaustive or to limit the disclosure to the precise forms disclosed. While specific implementations of, and examples for, the disclosure are described herein for illustrative purposes, various equivalent modifications are possible within the scope of the disclosure, as those skilled in the relevant art will recognize.

These modifications may be made to the disclosure in light of the above detailed description. The terms used in the following claims should not be construed to limit the disclosure to the specific implementations disclosed in the specification and the claims. Rather, the scope of the disclosure is to be determined entirely by the following claims, which are to be construed in accordance with established doctrines of claim interpretation.

Example 1: an apparatus, comprising: a layer, wherein the layer is a solid layer of glass; an opening through the layer; and a via in the opening, wherein the via comprises: a first material, wherein the first material comprises at least one metallic element; and a second material, wherein the second material comprises carbon.

Example 2: the apparatus of Example 1, wherein the second material comprises graphene.

Example 3: the apparatus of Example 1, wherein the second material comprises carbon nanotubes.

Example 4: the apparatus of Examples 1-3, wherein the first material comprises copper.

Example 5: the apparatus of Examples 1-4, wherein a volume percentage of the first material in the via is at least 25 volume percent.

Example 6: the apparatus of Examples 1-5, wherein the layer has a first coefficient of thermal expansion (CTE) and the via has a second CTE, wherein a difference between the first CTE and the second CTE is less than 75%.

Example 7: the apparatus of Examples 1-6, wherein the layer has a first coefficient of thermal expansion (CTE) and the via has a second CTE, wherein the first CTE and the second CTE are both below 6 parts per million/° C. (ppm/° C.).

Example 8: the apparatus of Examples 1-7, wherein the second material is homogenously dispersed throughout the first material.

Example 9: the apparatus of Examples 1-8, wherein the glass comprises silicon and oxygen.

Example 10: the apparatus of Examples 1-9, further comprising: a liner between the via and a surface of the layer.

Example 11: an apparatus, comprising: a layer, wherein the layer is a solid layer of glass; an opening through the layer; and a via in the opening, wherein the via comprises at least 70 percent carbon by volume.

Example 12: the apparatus of Example 11, wherein the via comprises carbon nanotubes.

Example 13: the apparatus of Example 11 or Example 12, wherein the via is in direct contact with a sidewall of the opening.

Example 14: the apparatus of Examples 11-13, wherein the layer has a first coefficient of thermal expansion (CTE) and the via has a second CTE, wherein a difference between the first CTE and the second CTE is less than 75%.

Example 15: the apparatus of Examples 11-14, wherein the layer has a first coefficient of thermal expansion (CTE) and the via has a second CTE, wherein the first CTE and the second CTE are both below 6 parts per million/° C. (ppm/° C.).

Example 16: the apparatus of Examples 11-15, wherein the glass comprises silicon and oxygen.

Example 17: a system, comprising: a board; a package substrate on the board, wherein the package substrate comprises: a glass layer; and a via through the glass layer, wherein the via comprises at least five percent by volume carbon, and wherein the via is electrically conductive; and a die on the package substrate.

Example 18: the system of Example 17, wherein the via comprises at least 25 volume percent copper.

Example 19: the system of Example 17 or Example 18, wherein the carbon is arranged as a carbon nanotube or graphene.

Example 20: the system of Examples 17-19, wherein the system is part of a personal computer, a server, a mobile device, a tablet, or an automobile.

What is claimed is:

1. An apparatus, comprising:
a layer, wherein the layer is a solid layer of glass;
an opening through the layer; and
a via in the opening, wherein the via comprises:
a first material, wherein the first material comprises at least one metallic element; and
a second material, wherein the second material comprises carbon.

2. The apparatus of claim 1, wherein the second material comprises graphene.

3. The apparatus of claim 1, wherein the second material comprises carbon nanotubes.

4. The apparatus of claim 1, wherein the first material comprises copper.

5. The apparatus of claim 1, wherein a volume percentage of the first material in the via is at least 25 volume percent.

6. The apparatus of claim 1, wherein the layer has a first coefficient of thermal expansion (CTE) and the via has a second CTE, wherein a difference between the first CTE and the second CTE is less than 75%.

7. The apparatus of claim 1, wherein the layer has a first coefficient of thermal expansion (CTE) and the via has a second CTE, wherein the first CTE and the second CTE are both below 6 parts per million/° C. (ppm/° C.).

8. The apparatus of claim 1, wherein the second material is homogenously dispersed throughout the first material.

9. The apparatus of claim 1, wherein the glass comprises silicon and oxygen.

10. The apparatus of claim 1, further comprising:
a liner between the via and a surface of the layer.

11. An apparatus, comprising:
a layer, wherein the layer is a solid layer of glass;
an opening through the layer; and
a via in the opening, wherein the via comprises at least 70 percent carbon by volume.

12. The apparatus of claim 11, wherein the via comprises carbon nanotubes.

13. The apparatus of claim 11, wherein the via is in direct contact with a sidewall of the opening.

14. The apparatus of claim 11, wherein the layer has a first coefficient of thermal expansion (CTE) and the via has a second CTE, wherein a difference between the first CTE and the second CTE is less than 75%.

15. The apparatus of claim 11, wherein the layer has a first coefficient of thermal expansion (CTE) and the via has a second CTE, wherein the first CTE and the second CTE are both below 6 parts per million/° C. (ppm/° C.).

16. The apparatus of claim 11, wherein the glass comprises silicon and oxygen.

17. A system, comprising:
a board;
a package substrate on the board, wherein the package substrate comprises:
a glass layer; and
a via through the glass layer, wherein the via comprises at least five percent by volume carbon, and wherein the via is electrically conductive; and
a die on the package substrate.

18. The system of claim 17, wherein the via comprises at least 25 volume percent copper.

19. The system of claim 17, wherein the carbon is arranged as a carbon nanotube or graphene.

20. The system of claim 17, wherein the system is part of a personal computer, a server, a mobile device, a tablet, or an automobile.
